(19) United States
(12) Patent Application Publication
(10) Pub. No.: US 2008/0176059 A1
(43) Pub. Date: Jul. 24, 2008

(54) Composite material constituted by a porous matrix and nanoparticles of metal or metal oxide

(75) Inventors: Roland Benoit, Orleans (FR); Mona Treguer-Delapierre, Villenave D'ornon (FR); Marie-Louise Saboungi, Orleans (FR)

Correspondence Address: SUGHRUE MION, PLLC, 2100 PENNSYLVANIA AVENUE, N.W., SUITE 800, WASHINGTON, DC, 20037, US

(73) Assignees: CENTRE NATIONAL DE LA RECHERCHE SCIENTIFIQUE, Paris (FR); UNIVERSITY D'ORLEANS, Orleans (FR)

(21) Appl. No.: 11/889,454

(22) Filed: Aug. 13, 2007

Related U.S. Application Data
(63) Continuation of application No. PCT/FR2006/000357, filed on Feb. 16, 2006.

(30) Foreign Application Priority Data
Feb. 24, 2005 (FR) 0501879

(51) Int. Cl. B32B 3/26; C23C 16/48

(52) U.S. Cl. 428/315.5; 427/595

(57) ABSTRACT

The invention relates to a composite material constituted by a microporous or mesoporous matrix and nanoparticles of metal or of metal oxide. The material being wherein the material of the matrix is either disordered, or ordered and optionally oriented, and wherein the nanoparticles are i) monodisperse in size when said matrix material is ordered and optionally oriented; ii) either monodisperse in size or of size identical to the size of the pores of the matrix material when said matrix material is disordered. The method of preparing the material consists in impregnating a microporous or mesoporous solid material with a solution of nanoparticle precursors, then in reducing the precursors within said material forming the matrix. Impregnation is performed under saturated vapor pressure and under reflux of the precursor solution, and reduction is performed radiolytically.

The present invention relates to a composite material constituted by a porous matrix and nanoparticles of metal or metal oxide.

### BACKGROUND OF THE INVENTION

Composite materials constituted by a microporous or mesoporous mineral matrix within which monodisperse metallic nanoparticles are distributed uniformly and at high concentration are of great interest in a variety of fields such as optics, magnetoresistance, thermoelectricity, and catalysis. When preparing such materials, the problem is to control the size and the distribution of the particles, and also the distance between the particles within the solid.

Various physicochemical methods for preparing such composite materials have been proposed in the prior art. They generally consist in impregnating the porous solid matrix with a solution of precursors for metallic particles, then in reducing the precursor within the solid matrix, either chemically, or thermally, or radiolytically, or photochemically, or electrolytically. For example, Kuei-Jung Chao et al. [Preparation and characterization of highly dispersed gold nanoparticles within channels of mesoporous silica”, Catalysis Today (2004), Vol. 97, Issue 1, pp. 49-53] describes a method consisting in impregnating porous silica with an acid solution of HAuCl₄ or for a solution of NaCuAl₄, and then in reducing by heating under a hydrogen atmosphere.

Methods of impregnation by means of a solution present numerous drawbacks. The extent of impregnation by the precursor solution is small and non-uniform within the solid matrix. As a result firstly the content of nanoparticles after reduction within the matrix remains relatively small, generally less than 30% by volume, and secondly the nanoparticles are concentrated essentially close to the surface of the porous matrix, over a thickness of about 20 nanometers (nm). In addition, the particle size distribution is large.

Various tests have been performed to improve the content and the uniformity of impregnation of the porous solid matrix. Thus, proposals have been made to increase the duration of the impregnation step (up to a few weeks), while subjecting the medium to ultrasound or to moderate heating. Nevertheless, those treatments yield only a small improvement and they run the risk of degrading the porous solid. Proposals have also been made to impregnate the porous solid matrix iteratively, by proceeding with a plurality of impregnation and reduction cycles. That has made it possible to increase greater impregnation contents. Nevertheless, the method is lengthy and it runs the risk of producing particles of non-uniform size in the solid because it is possible during a given cycle to reduce metal precursors onto metal particles that were formed during an earlier cycle.

It has also been envisaged that the metallic nanoparticles can be produced and then dispersed within a solid porous matrix. For example, EP-1 187 230 describes a method of preparing a thermoelectric material, the method comprising a step during which the target material is irradiated with a laser beam and the particles are recovered in a vacuum, and a second step during which the particles recovered in a vacuum are deposited on the substrate. The main drawback of that method is that it does not enable a uniform distribution of nanoparticles to be obtained within the matrix, with its surface zone being the most rich.

U.S. Pat. No. 6,670,539 describes a method of preparing a composite material constituted by a porous matrix in which the pores have a mean size of 5 nm to 15 nm, and by nanowires of bismuth or bismuth alloy. The method consists in causing bismuth vapor to pass into the pores of the matrix. The porous matrix is then cooled to cause the bismuth vapor to condense progressively in the pores between the vapor inlet and the vapor outlet, so as to form nanowires of bismuth progressively in the pores. Nevertheless, the progressive condensation of bismuth vapor in the matrix is limited by the size of the mesopores, and it is not uniform. Non-uniform condensation makes it difficult to control nucleation reactions and nanowire growth. This results in discontinuity of the nanowire, and grain joints that encourage the appearance of phonons and disturb the propagation of electrons. Furthermore, in that document, it is stated that the improvement in the figure of merit is associated with confinement that is three-dimensional and not only two-dimensional. In U.S. Pat. No. 6,670,530, proposals are also made to prepare a composite material by placing a porous solid matrix in a vapor of a solution of a precursor for the desired nanoparticles. Nevertheless, in that method, it is necessary to force the vapor to pass through the solid porous matrix, which requires complicated apparatus. In addition, it is found that the forced passage of vapor through the matrix can lead to rupturing of the matrix, which is fragile because of its porous nature. In addition, the thermal constraints (T>590° C.) of that method are not compatible with using mesoporous materials for which the melting point is lower than that temperature.

### OBJECT AND SUMMARY OF THE INVENTION

The object of the present invention is to provide an effective method of producing a composite material constituted by a microporous or mesoporous solid matrix, with metal or metallic oxide nanoparticles being distributed within the pores thereof in a manner that is uniform and at a high concentration. That is why the present invention provides a method of preparing a composite material, and also the resulting composite material.

The method of preparing a composite material according to the present invention consists in impregnating a microporous or mesoporous solid material with a solution of one or more precursors of metallic nanoparticles or of metal oxide nanoparticles, then in reducing the precursors within said matrix-forming material. The method being wherein impregnation is performed under saturated vapor pressure and under reflux of the precursor solution, and wherein the reduction is performed radiolytically.

The precursor solution may also contain an interceptor agent for intercepting oxidizing radicals, which agent intercepts the oxidizing radicals formed in the solution during the irradiation, thus avoiding oxidation of the colloidal particles that are produced. The oxidizing radical interceptor is preferably selected from primary alcohols, secondary alcohols, and formates. By way of example, mention can be made of isopropanol and of alkali metal formates. The oxidizing radical interceptors perform two functions: not only do they capture the oxidizing radicals that arise during radiology, but they also provide new reducing radicals, that stem from their own reaction with the oxidizing radicals. This serves to increase the reduction yield of metal. When the precursor solution contains the interceptor agent in sufficient quantity, the resulting nanoparticles are constituted by the metal. When the reaction medium is in oxidizing conditions (e.g. when the oxidizing radical interceptor agent content is zero or small, or in the presence of traces of oxygen, or when the pH of the medium is acidic), the nanoparticles formed after reduction are particles of an oxide of the metal of the precursor compound. The concentration of the radical interceptor is determined as a function of the quantity and the nature of the metal that is to be reduced, and as a function of the nature of the desired particles. Thus, for a concentration ratio of “interceptor agent”/“precursor metallic salt” that is less than or equal to a value of about 10⁻² to 10⁻¹, the nanoparticles are generally oxide nanoparticles. For a concentration ratio “interceptor”/“precursor metallic salt” not less than a value of about 10³ to 10⁴, the nanoparticles are generally nanoparticles of metal. Determining very precise concentration ranges adapted to each type of metal for forming either metal nanoparticles or metal oxide nanoparticles, comes within the competence of the person skilled in the art.

The microporous or mesoporous materials for forming the composite material matrix may be selected from silica, alumina, zeolites, metallic oxides such as zirconia, titanium oxide, and polymers presenting mesoporosity [such as for example polystyrene, and copolymers of divinylbenzene (DVB) and ethylenegylcol dimethacrylate (EDMA)].

The term “microporous” is used to designate pores having a mean dimension of less than a nanometer. The term “mesoporous” is used to designate pores having a mean dimension in the range 1 nm to 100 nm.

In a microporous or mesoporous material for forming the matrix of the composite material of the invention, the distribution of pores at nanometer scale can be disordered or ordered. A disordered distribution is generally constituted by open cavities distributed in disordered manner. An ordered pore distribution may be oriented or non-oriented. A non-oriented ordered pore distribution may be constituted by cavities interconnected by tunnels. A distribution that is both ordered and oriented may be constituted, for example, by channels distributed in regular hexagonal form with few defects. In the text below, the term “disordered material” is used to mean a material in which the pore distribution is disordered, and the term “optionally oriented ordered material” is used to mean a material in which the pore distribution is ordered, and optionally oriented.

The precursors are selected from compounds of the following metals: Bi, Au, Ag, Ti, Mg, Al, Be, Mn, Zn, Cr, Cd, Co, Ni, Mo, Sn, Pb. The compounds may be inorganic salts (such as for example sulfates or perchlorates), or organic salts such as formates or neodecanoates. As an example of a neodecanoate, mention can be made of bismuth neodecanoate. Neodecanoates enable reduction to be performed in a non-aqueous medium. The precursors may also be selected from organometallic compounds. By way of example, mention can be made of diphenyl magnesium, diphenyl beryllium, triisobutyl aluminum, biscyclopentadienyl chromium, biscyclopentadienyl titanium, biscyclopentadienyl manganese, tetracarbonyl cobalt, tetracarbonyl nickel, hexacarbonyl molybdenum, dipropyl cadmium, tetraallyl zinc, and tetrapropyl lead. The solvent of the precursor solution is selected as a function of the precursor salt in question. By way of example, mention can be made of water, organic alcohols, ammonia, and acetonitrile.

The radiolytic reduction may be performed using a gamma ray source, an X-ray source, or a source of accelerated electrons.

A composite material obtained by the method of the invention is constituted by a matrix constituted by a microporous solid material having pores with a mean size less than one nanometer or by a mesoporous solid material having pores with a mean size in the range 1 nm to 100 nm, and by nanoparticles of metal or of metal oxide. The material being wherein the material of the matrix is either disordered, or ordered, and optionally oriented, and wherein:

the nanoparticles are monodisperse in size and represent 50% to 67% of the total pore volume of the matrix material, when said matrix material is ordered and optionally oriented; and

the nanoparticles are either monodisperse in size, or are of size identical to the size of the pores of the matrix material, and they represent at least 50% of the initial volume of the pores of the matrix material when said matrix material is disordered.

The monodisperse characteristic for materials constituting the subject matter of the present invention is characterized by a ratio <d>/dₘₐₓ of less than 10%, where d is the diameter of the nanoparticle.

### BRIEF DESCRIPTION OF THE DRAWINGS

FIGS. 1a and 1b are diagrammatic views of a composite material in which the distribution of pores in the matrix material is disordered, respectively before and after impregnation;

FIGS. 2a and 2b are diagrammatic views of a composite material in which the pore distribution in the matrix material is ordered and oriented, respectively before and after impregnation;

FIG. 3 shows in the top portion a TEM micrograph of a sample and in the bottom portion the pore distribution in the sample;

FIG. 4 shows an apparatus for implementing the method 15 of the invention;

FIG. 5 is a dark field TEM micrograph of a silica-based mesoporous matrix in which bismuth nanoparticles have been formed;

FIG. 6 shows a X-ray diffraction diagram of the sample of FIG. 5;

FIG. 7 shows a TEM micrograph of another sample.

### MORE DETAILED DESCRIPTION

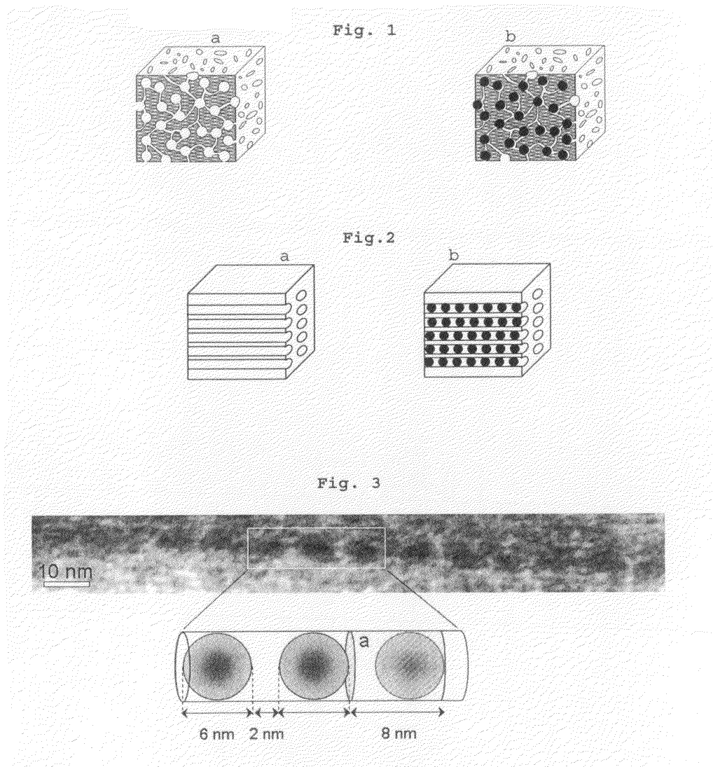

In a composite material in which the material of the matrix is disordered, the size of the nanoparticles depends in particular on the rate at which the irradiation dose is delivered, on the initial concentration of precursor, and on pore size. A high irradiation rate encourages the production of a large number of nucleation centers. With growth that is not limited, e.g. by a dose effect or a precursor concentration effect, the nanoparticles remain monodisperse in size so long as the size remains smaller than that of the pores. FIGS. 1a and 1b are diagrammatic views of a composite material in which the distribution of pores in the matrix material is disordered, respectively before and after impregnation.

FIGS. 2a and 2b are diagrammatic views of a composite material in which the pore distribution in the matrix material is ordered and oriented, respectively before and after impregnation. The micropores are in the form of cylindrical channels. When the nanoparticles come into contact with one another, the residual porosity corresponding to the empty spaces between the nanoparticles is 33%. This embodiment is shown diagrammatically in FIG. 3.

The solid matrix is constituted by a material selected from silica, alumina, zeolites, metallic oxides such as zirconia, titanium oxide, polymers such as polystyrene, and copolymers that present mesoporosity. When the porosity of the matrix material is ordered and optionally oriented in the form of channels, the nanoparticles are distributed uniformly throughout the volume of the matrix.

The nanoparticles are made of a metal selected from: Bi, Au, Ag, Ti, Mg, Al, Be, Mn, Zn, Cr, Cd, Co, Ni, Mo, Sn, and Pb, or by an oxide of one of those metals.

As examples of materials of the invention, mention can be made of:

a material comprising a matrix of open-pored disordered mesoporous silica containing nanoparticles of bismuth, gold, or silver;

a material comprising a matrix of optionally oriented, ordered mesoporous silica having pores in the form of regular channels, containing bismuth nanoparticles; and

a material comprising a matrix of open-pored mesoporous alumina containing nanoparticles of bismuth, gold, or silver.

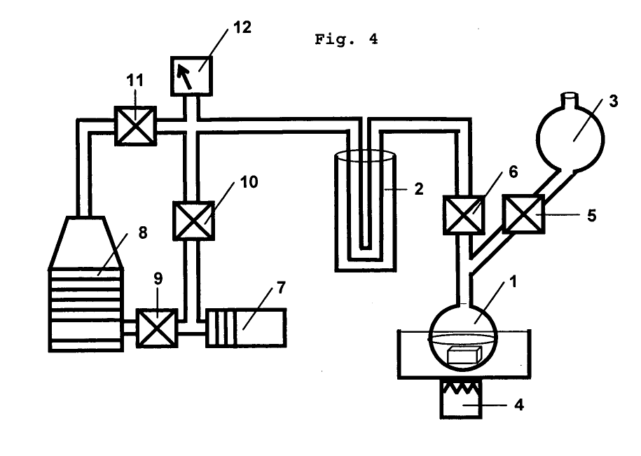

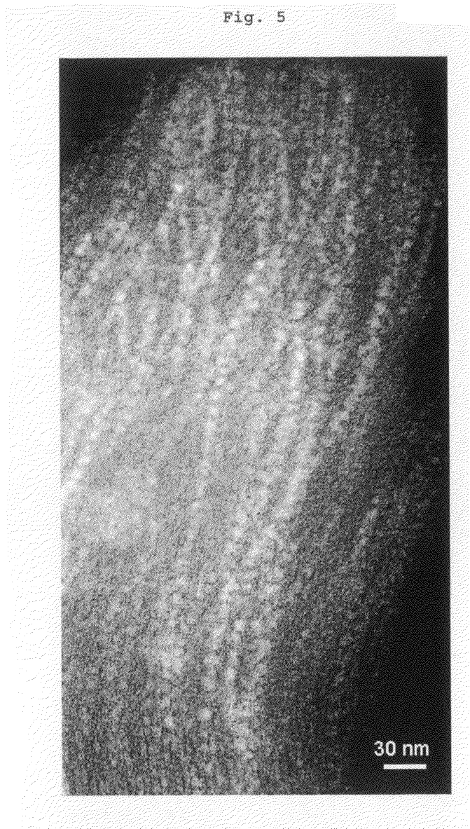

The method of the invention may be implemented in apparatus as shown in FIG. 4. Said apparatus comprises an impregnation chamber and a pump system. The impregnation chamber comprises an irradiation cell 1, a liquid nitrogen trap 2, a tank of precursor solution 3, heater means 4, and irradiation means (not shown). A pipe including a valve 5 connects the irradiation cell 1 to the tank 3. A pipe including a valve 6 connects the irradiation cell 1 to the liquid nitrogen trap 2. The pump system comprises: a primary pump 7; a secondary pump 8; pipes provided with valves 9, 10, and 11; and a vacuum-measuring device 12. The pump system enables a vacuum to be obtained that is at the limit of a secondary vacuum, having a value of 10⁻⁷ mbar.

Materials of the invention can be used in a variety of technical fields. In particular, materials having a mesoporous matrix and bismuth nanoparticles are particularly useful in thermoelectricity and in magnetoresistance.

In the field of thermoelectric materials, bismuth is known for its good thermoelectrical properties, in particular for 2D and 1D quantum confinement. In that type of confinement, the figure of merit remains less than 2. That limit is due essentially to phonon propagation. In a material of the present invention, having a mesoporous matrix and bismuth nanoparticles, phonon propagation is decreased.

That is why the present invention also provides the use of materials of the invention comprising a mesoporous matrix and bismuth nanoparticles as a thermoelectric material, in particular as a generator of low temperature, or conversely as a generator of voltage. As a generator of low temperature, the composite material containing bismuth nanoparticles can be used for example in the design of a refrigerator, an air conditioned seat for a car, an air conditioner for a car, an icebox, a thermostatic enclosure, or a radiator for an electronic circuit. As a generator of voltage, the composite material containing bismuth nanoparticles can be used for example as a direct source of energy or as a component of a storage battery.

When the composite material of the invention containing bismuth nanoparticles is used in the field of magnetoresistance, the size effect considerably increases the property of magnetoresistance, and magnetoresistance is then said to be “large”. A magnetoresistance value is said to be “large” when it presents a relative increase of 50% compared with the values for conventional magnetoresistive materials. This increase is defined using the following formula:

(R−R(H))/R>50%

where R represents the resistance of the material without a magnetic field and R(H) represents the resistance of the material when subjected to a magnetic field. By way of example, this increase reaches 50% with bismuth at a temperature of 300 K and a field of 32 tesla (T). When this property is desired, the composite material of the invention can be used as a magnetic sensor, for example in the fabrication of magnetic field detector or reader heads.

The invention is illustrated below by an example of preparing a composite material, however the invention is not limited thereto.

### EXAMPLE 1

### Preparing a Composite Material Comprising a Silica Matrix that is Oriented and Ordered, Together with Nanoparticles of Bismuth

The preparation was performed in apparatus analogous to that described above. The irradiation cell was initially stoved at 80° C. by a water bath in order to degasify and decontaminate the surfaces of the cell so as to avoid particles forming on the walls.

Both a precursor solution (bismuth perchlorate in water at a concentration of 0.6 moles per liter (mol/L)), and a solution of oxidizing radical interceptor agent (isopropanol in water at 7 mol/L) were prepared.

A sample of mesoporous silica was prepared using the method described by Dongyuan Zhao, Qisheng Huo, Jianglin Feng, Bradley F. Chmelka, and Galen D. Stucky [J. Am. Chem. Soc. 1998, 120, 6024-6036]. 4.0 grams (g) of Brij 96® surfactant were dissolved in 20 g of water and 80 g of 2M HCl, while stirring. To the resulting uniform solution, 8.80 g of tetraethoxysilane were then added at ambient temperature while continuing to stir for 20 hours (h). The solid product was recovered, washed, and dried at ambient temperature. The material as obtained in this way was heated from ambient temperature up to a temperature of 500° C. over a duration of 8 h. Thereafter, a pause was implemented for 6 h prior to allowing the material to cool down to ambient temperature.

The dimensions of the sample were a few millimeters. The pores had a size of 6 nm and the total porosity of the sample was 80% of the total volume. Its BET surface area was 342 square meters per gram (g/m²).

With the valves 5 and 6 of the apparatus closed, the precursor solution was introduced into the tank 3 and the silica sample was introduced into the irradiation cell 1.

In a first step, the valve 6 was opened and the silica sample was processed under a vacuum of 10⁻⁶ mbar while heating to a temperature of 80° C. using the heater means 4 in order to desorb all of the impurities and water present at the surface. At the end of that operation, the valve 6 was closed, thereby putting the cell under a static vacuum. Thereafter, the valve 5 was opened in order to introduce the precursor solution into the irradiation cell. On contact with the silica, the precursor solution vaporized immediately. After introducing the precursor solution, the valve 5 was reclosed and the valve 6 was partially opened in order to evacuate the irradiation cell using the primary pump system, until all of the dissolved gas had been pumped out as characterized by the irradiation cell 1 cooling. At that moment, the valve 5 was closed in order to isolate the irradiation cell 1, and it was heated up to the saturated vapor pressure of the precursor solution under a partial vacuum. A reflux phenomenon was observed in the cell 1. Heating was maintained for a duration of 2 h. This duration is a function both of the size and of the porosity of the single piece forming the sample.

Thereafter, by means of the tank 3, the isopropanol solution was introduced into the cell 1, by opening the valve 5. The valve 5 was reclosed after the isopropanol had been introduced. By opening the valve 6, the irradiation cell 1 was again evacuated until it had cooled down. The isopropanol solution diffused quickly in the precursor solution. The mixture was then again put into reflux for one hour, and then sealed under a vacuum. Sealing under a vacuum at the end of the step of refluxing the mixture could be replaced by isolating the sample in the cell 1 at atmospheric pressure, and sweeping the cell with argon for 30 minutes (min).

Thereafter, the impregnated piece of silica was subjected to irradiation using a cesium 137 gamma ray source with a power of 1.8 kilograys per hour (kGy.h⁻¹) for one hour. The piece was then dried directly in the cell 1 under a primary vacuum and then under a secondary vacuum. The sample obtained was characterized by transmission electron microscope (TEM), BET, and X-ray.

The BET surface area of the sample at the end of the process was 60 m²/g, which represents a decrease of 87% compared with its initial value.

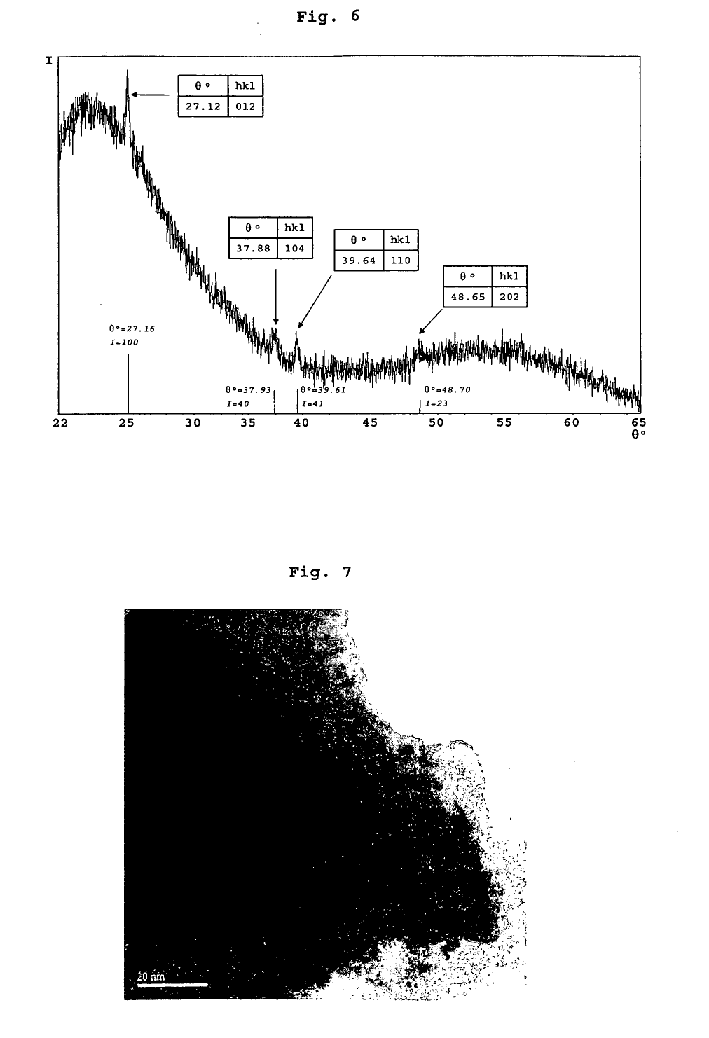

FIG. 5 is a dark field TEM micrograph of the silica-based mesoporous matrix in which bismuth nanoparticles have been formed. The micrograph clearly shows the presence of crystallized nanoparticles throughout the mesoporous matrix. The nanoparticles appear white and have a size of 6.0 nm±0.5 nm. Under the electron beam of the transmission electron microscope, the nanoparticles are caused to turn. Thus, as a function of their orientation, they either do or do not diffract. That explains why micrographs of this type show only a fraction of all of the nanoparticles present in the silica lattice. FIG. 5 shows that it is possible to produce stable crystallized nanoparticles at high concentration and at small spacing within organized mesoporous silica.

The structure of the silica/bismuth sample in which the micropores of the matrix are of the type that is ordered and oriented in the form of cylindrical channels is also shown in above-described FIG. 3. In FIG. 3, the top portion is a transmission electron microscope (TEM) micrograph of a sample of material showing the alignment of the nanoparticles of bismuth metal in a channel. It constitutes an enlarged view of the sample shown in FIG. 5. The bottom portion is a diagram of a portion of the channel. It shows how impregnation varies and the limits on impregnation percentage as a function of the periodic distance a between spherical nanoparticles of bismuth. When the bismuth nanoparticles are in contact with one another, the residual porosity corresponding to the empty spaces between the nanoparticles is 33%.

The X-ray diffraction diagram is shown in FIG. 6, which also shows the intensity of lines in accordance with the JCPDS 05-0519 card. Intensity I is plotted up the ordinate, and the angle θ is plotted along the abscissa. The curve corresponds to the present example of material in accordance with the invention. The lines marked I=100, I=40, etc., correspond to the lines of the JCPDS 05-0519 card. On the continuous background that results from the mesoporous silica, there can be seen the four diffraction peaks of metallic bismuth. The intensity of these rays relative to the continuous background is small, which is associated with the high absorption power of bismuth, having a mass absorption coefficient of 15 square centimeters per gram (cm²/g) for a Cu-K-alpha X-ray source at 1.6 kilowatts (kW) and 40 kiloelectron volts (KeV). Comparing the spectrum with the data of the 05-0519 card of the JCPDF database confirms that the nanoparticles formed were of bismuth metal and not of bismuth oxide.

### EXAMPLE 2

### Preparing a Material having a Mesoporous Silica Matrix that is Disordered with Open Pores, Containing Nanoparticles of Bismuth

The same operations were performed as in Example 1, however the following steps were modified.

The disordered silica matrix was obtained by the method described by Polartz et al. [Chemical communication (2002), pp. 2593-2604] and by Göltner et al. [Advanced materials (1991), Vol. 9, Issue 5]. 3 g of a block copolymer (polystyrene-b-poly(ethylene oxide)) were dissolved in 6 g of trimethoxysilane (TMOS), and then 3 g of hydrochloric acid HCl were added. The methanol present in the form of solvent in the TMOS was removed by vacuum evaporation and the resulting gel was stoved at 60° C. for 24 h. The copolymer was then removed by heating to 750° C. for 12 h under a stream of oxygen. The dimensions of the sample were a few millimeters. The pore size lay in the range 2 mm to 4 mm and the total porosity of the sample was 70% of the total volume. The BET surface area was 580 g/m².

Irradiation was performed using a cesium 137 gamma ray source with a power of 1.8 kGy.h⁻¹ for a duration of 2 h. FIG. 7 shows the TEM micrograph of the resulting material. Image analysis confirms an impregnation ratio greater than 70% in a material whose initial porosity, measured by BET was 80%. The sizes and the shapes of the particles match those of the pores, because of the high irradiation rate.

### EXAMPLE 3

### Preparing a Composite Material Comprising a Disordered Silica Matrix Containing Nanoparticles of Silver

Both a 10 millimoles (mM) precursor solution of silver sulfate Ag₂SO₄ with protection against light to avoid any photochemical decomposition, and a solution of an oxidizing radical interceptor agent (isopropanol in water at 7 mol/L) were prepared.

A piece of disordered silica was prepared using the method mentioned in Example 2. The method of impregnating the silver salt was identical to that of Example 1. The cells 1 and 3 were covered in sheets of aluminum in order to protect the precursor from light rays. Thereafter, the piece of impregnated silica was irradiated using a cesium 137 gamma ray source with power of 1.8 kGy.h⁻¹ for one hour. The piece was then dried directly in the cell 1 under a primary vacuum and then a secondary vacuum.

What is claimed is:

1. A method of preparing a composite material, the method consisting in impregnating a microporous or mesoporous solid material with a solution of one or more precursors of metallic nanoparticles or of metal oxide nanoparticles, then in reducing the precursors within said matrix-forming material, the method being wherein impregnation is performed under saturated vapor pressure and under reflux of the precursor solution, and wherein the reduction is performed radiolytically.

2. A method according to claim 1, wherein the precursor solution also contains an oxidizing radical interceptor agent.

3. A method according to claim 2, wherein the concentration ratio of “interceptor agent”/“precursor metallic salt” is not less than the value of about 10³ to 10⁴.

4. A method according to claim 2, wherein the concentration ratio of “interceptor agent”/“precursor metallic salt” is less than or equal to a value of about 10⁻² to 10⁻¹.

5. A method according to claim 1, wherein the microporous or mesoporous material is selected from: silica, alumina, zeolites, metallic oxides such as zirconia, titanium oxide, and polymers that present mesoporosity.

6. A method according to claim 1, wherein the distribution of pores at nanometer scale in the microporous or mesoporous material is disordered.

7. A method according to claim 1, wherein the distribution of pores at nanometer scale in the microporous or mesoporous material is ordered and optionally oriented.

8. A method according to claim 1, wherein the nanoparticle precursor(s) is/are selected from compounds of: Bi, Au, Ag, Ti, Mg, Al, Be, Mn, Zn, Cr, Cd, Co, Ni, Mo, Sn, and Pb.

9. A method according to claim 8, wherein the nanoparticle precursor compound is an inorganic salt, an organic salt, or an organometallic compound.

10. A method according to claim 9, wherein the inorganic salt is a sulfate or a perchlorate.

11. A method according to claim 9, wherein the organic salt is a formate or a neodecanoate.

12. A method according to claim 11, wherein the precursor is a bismuth neodecanoate.

13. A method according to claim 9, wherein the precursor compound is an organometallic compound selected from diphenyl magnesium, diphenyl beryllium, triisobutyl aluminum, biscyclopentadienyl chromium, biscyclopentadienyl titanium, biscyclopentadienyl manganese, tetracarbonyl cobalt, tetracarbonyl nickel, hexacarbonyl molybdenum, dipropyl cadmium, tetraallyl zinc, and tetrapropyl lead.

14. A method according to claim 2, wherein the oxidizing radical interceptor is a primary alcohol, a secondary alcohol, or an alkaline metal formate.

15. A method according to claim 1, wherein the radiolytic reduction is performed using a gamma ray source, an X-ray source, or a source of accelerated electrons.

16. A composite material constituted by a matrix constituted by a microporous solid material having pores with a mean size less than one nanometer or by a mesoporous solid material having pores with a mean size in the range 1 nm to 100 nm, and by nanoparticles of metal or of metal oxide, the material being wherein the material of the matrix is either disordered, or ordered, and optionally oriented, and wherein:
the nanoparticles are monodisperse in size and represent 50% to 67% of the total pore volume of the matrix material, when said matrix material is ordered and optionally oriented; and
the nanoparticles are either monodisperse in size, or are of size identical to the size of the pores of the matrix material, and they represent at least 50% of the initial volume of the pores of the matrix material when said matrix material is disordered.

17. Composite material according to claim 16, wherein the solid matrix is constituted by a material selected from silica, alumina, zeolites, metallic oxides, and polymers that present mesoporosity.

18. A composite material according to claim 16, wherein the nanoparticles are constituted by a metal selected from: Bi, Au, Ag, Ti, Mg, Al, Be, Mn, Zn, Cr, Cd, Co, Ni, Mo, Sn, and Pb, or by an oxide of one of said metals.

19. A composite material according to claim 16, wherein the matrix material is mesoporous and the nanoparticles are constituted by bismuth.

20. A composite material according to claim 16, wherein the microporosity of the matrix is of the ordered and oriented type, being in the form of cylindrical channels, and the nanoparticles are in contact with one another, the residual porosity corresponding to the empty spaces between the nanoparticles being 33%.

21. The use of a composite material according to claim 19, as a thermoelectric material.

22. A low temperature generator including a material according to claim 19 as its active material.

23. A voltage generator including a material according to claim 19 as its active material.

24. The use of a composite material according to claim 19, as a magnetoresistive material presenting large magnetoresistance.

25. A magnetic sensor, including as active material a material according to claim 19.
